(19) United States
(12) Patent Application Publication
(10) Pub. No.: US 2025/0372998 A1
(43) Pub. Date: Dec. 4, 2025

(54) FULL ELECTRONIC CIRCUIT BREAKER USING CURRENT SENSOR MEASURING ELECTROMAGNETIC WAVE

(71) Applicants: ELECTRONICS AND TELECOMMUNICATIONS RESEARCH INSTITUTE, Daejeon (KR); EG KOREA CO., LTD., Busan (KR)

(72) Inventors: Hyun-Tak KIM, Daejeon (KR); Chulbum JOO, Busan (KR); Tae Moon ROH, Daejeon (KR)

(21) Appl. No.: 18/707,523

(22) PCT Filed: Oct. 20, 2022
(86) PCT No.: PCT/KR2022/016016

§ 371 Date: May 3, 2024

(30) Foreign Application Priority Data
Nov. 5, 2021 (KR) 10-2021-0151716

(51) Int. Cl. H02H 1/00; G01R 19/165; H02H 3/093; H03M 1/12

(52) U.S. Cl. CPC H02H 1/0092; G01R 19/16547; H02H 3/0935; H03M 1/12

(57) ABSTRACT

The present disclosure relates to the development of a full electronic overcurrent breaker in which an overcurrent tripping time continuously decreases as the overcurrent increases and then discontinuously decreases at a critical overcurrent using a hyun-tak line current sensor (Korean Patent Registration No. 10-1981640) without saturation in large current. The full electronic overcurrent breaker 300 includes a sensor unit 310, a sensor signal amplifier unit 320, a comparison unit 330, an analog-to-digital converter unit 340, a CPU unit 350, a switch unit 380 that trips overcurrent, a power supply unit 395, a memory unit 360. According to this disclosure, (1) an overcurrent gap between the short time and the instantaneous time, (2) the long time trip at the upper limit of the short time, and (3) the complexity of set switch at a set time, which are issues of conventional commercialized electronic overcurrent breakers, are solved.

### CROSS-REFERENCE TO RELATED APPLICATIONS

This application is the National Stage filing under 35 U.S.C. 371 of International Application No. PCT/KR2022/016016, filed on Oct. 20, 2022, which claims the benefit of Korean Patent Application No. 10-2021-0151716, filed on Nov. 5, 2021, the contents of which are all hereby incorporated by reference herein in their entirety.

### TECHNICAL FIELD

The present disclosure relates to a power circuit breaker, and more particularly, relates to a full electronic overcurrent breaker (FEOB) having both an instantaneous critical characteristic at a critical tripping current and a decreasing tripping time as overcurrent increases.

### BACKGROUND ART

According to the international standard IEC 60947, power circuit breakers trips power (FIG. 1) at a tripping time for a long time 20 within 2 hours relatively long at overcurrent (lover_current; lo_1st) that is 1.2 to 1.5 times of a rated current (I_{Reference}:I_{Ref}), for short time 30 within 2 minutes at overcurrent (lo_2nd) that is 1.5 to 7.2 times of the rated current (I_{Reference}:IRef), for an instantaneous time 40 within 2 minutes to 30 milliseconds at a very large critical overcurrent (instantaneous current) (lo_3rd=linst=(7.2 to 14)×Iref), and for the tripping time 50 of FIG. 1, it trips within 60 milliseconds (msec) at 7.2 times a maximum rated current within 30 milliseconds at 14 times of the maximum rated current in short-circuit currents exceeding 7.2 to 14 times the instantaneous rated current (maximum rated current).

The power circuit breakers are classified into an analog type overcurrent breaker and a digital type electronic overcurrent breaker (EOB). The analog circuit breaker uses the heat generated from the overcurrent including a bending phenomenon of a bimetal made by combining two metals with different thermal expansion coefficients as a switch. However, the circuit breaker using the bimetal is inaccurate because the bimetal reacts very sensitively to external temperature or the temperature of overcurrent, so the degree of bending is irregular and the metal characteristics change over time (secular change). The inaccuracy error is about 500% from minimum to maximum (FIG. 1). Nevertheless, the analog overcurrent circuit breaker has the advantage of inverse time characteristic that the tripping time is variable. It is because the degree of heat generation is different, which is depending on the magnitude of the overcurrent. The analog overcurrent circuit breaker has been used for more than 100 years since it was first invented in 1924 by Westinghouse (power equipment company of U.S.A.). The analog circuit breaker is capable of tripping of the long time 20, the short time 30, the instantaneous time 40, and short circuit 50, but it is very difficult to set.

In addition, there is an instantaneous circuit breaker that operates an electromagnet, which is a mechanical switch, using the strength of a magnetic field. However, this instantaneous circuit breaker not only does not trip the long time and the short time, but also has a problem in that the tripping characteristics change, which is depending on the installation method of the electromagnet.

In contrast, the conventional electronic circuit breaker (EOB) measures the current of the power wire with a CT (Current Transformer) current sensor or a Rogoski coil current sensor, and analyzes the digitized data with a microprocessor or microcontroller to directly control a power trip switch. Also, communication is also possible, so it has emerged as a new power circuit breaker in the electronic communication era. Current electronic circuit breakers are low-voltage circuit breakers. There are both an ACB (Air Circuit Breaker) 200 that extinguishes an arc using air and an EOCR (Electronic OverCurrent Relay) that trips the overcurrent of the motor.

Although the electronic circuit breaker (EOB) has been commercialized, the current sensors used in the EOB have the following disadvantages. The CT current sensor does not linearly measure high current, and current sensor of Rogoski coil does not measure low current (prior paper, FIG. 13B). To overcome these shortcomings, the EOB uses the CT current sensor and an instantaneous electromagnet circuit breaker or the Rogowski coil current sensor and the instantaneous electromagnetic circuit breaker.

For example, the EOB trips power electronically for the long time and the short time currents. However, when a very large current in a case such as a short or instantaneous time, comes in an instant, it operates a mechanical switch using a very large electromagnetic field to trip the power. This is not a complete EOB, but rather a mechanical circuit breaker. There is a fatal problem here as a circuit breaker. There is a large current gap between the electronic breaking and the mechanical breaking (problem 1). This gap can destroy a system.

In addition, in the case of short time trip instead of the instantaneous time, the power tripping time of the EOB is not variable according to the magnitude of the overcurrent, and a uniform tripping time (set time) is provided with respect to the overcurrent set in several stages (FIG. 2A). In this case, in the vicinity of the upper limit boundary point of the short time below the instantaneous current (large arrow in FIGS. 1 and 2) 60, for a very large current, there is a problem in that the power is tripped at a set time for a long time or a set time before it (problem 2). In other words, the power tripping time becomes longer. In addition, the EOCR, which trips the overcurrent of a motor, also has this problem.

For an additional given overcurrent, to set a fixed tripping time, there are at least 2 to 8 of rated current setting switches, overcurrent setting switches, and tripping time setting switches, externally, and since the number of setting cases is too large, it is actually very difficult to set (FIG. 2B). Therefore, the malfunction of circuit breakers may occur due to the wrong setting of a general user (problem 3).

For these reasons, it is difficult for overcurrent circuit breakers to obtain approval from the international standards IEC 60947-1 (motor overcurrent circuit breaker) and IEC 60947-2 (circuit, earth leakage, air circuit breaker) that prevent overcurrent. Therefore, the disclosure of a full electronic overcurrent breaker (FEOB) that solves the above problems is required.

Patent documents and non-patent documents described below are conventional art documents of the present disclosure.
(Patent Document 1) Registered Patent KR 10-1981640 (Title: Current sensor for measuring alternating current electromagnetic wave and circuit breaker using the same), Family Patent: Pub. No.: US 2020/0182913 A1, Current sensor for measuring alternating electromagnetic wave and a current breaker using the same.
(Patent Document 2) Registered Patent U.S. Pat. No. 4,250,532 (Electronic overcurrent detection and tripping circuit)
(Patent Document 3) Registered Patent U.S. Pat. No. 4,380,785 (Solid state trip unit for an electrical circuit breaker)
(Patent Document 4) Registered Patent U.S. Pat. No. 10,896,791 B2 (Dynamic coordination of protection devices in electrical distribution systems)
(Patent Document 5) Registered Patent U.S. Pat. No. 10,811,867 B2 (Hybrid air-gap/solid-state circuit breaker)
(Non-Patent Document 1) Lj. A. Kojovic, ‘Rogowski Coil Transient Performance and ATP Simulations for Applications in Protective Relaying’, Presented at the International Conference on Power Systems Transients (IPST'05) in Montreal, Canada on Jun. 19-23, 2005 Paper No. IPST05-010.

### DISCLOSURE

### Technical Problem

The problem to be solved by the present disclosure is to eliminate the gap of the overcurrent existing between the two types of tripping means used in the existing overcurrent circuit breaker (problem 1), to reduce the tripping time according to the increase of overcurrent with respect to tripping with the tripping time of the long time 20 or a step 130 before the short time step 120 at the upper limit boundary point (large arrow in FIGS. 1 and 2) 60 of the short time 120 in the short time step 120 due to non-instantaneous tripping (problem 2), and to eliminate many setting switches due to the existing set time setting (problem 3).

The two types of tripping means mean an electronic electromagnet relay tripping means by a semiconductor switch device for non-instantaneous overcurrent tripping, and a mechanical tripping means combined with an electromagnet switch for instantaneous overcurrent tripping. The reason for using this other tripping means is that the current sensor used in the electronic circuit breaker cannot measure from low current to high current.

### Technical Solution

To achieve the above object, the present disclosure provides a full electronic overcurrent breaker having no setting switches and having a function (FIG. 1) in which the tripping time decreases as the overcurrent increases and then discontinuously decreases at the critical overcurrent using a hyun-tak line current sensor 316 (50th paragraph of Patent Document 1) capable of measuring from low current to high current.

Here, the hyun-tak line in 50th paragraph of Patent Document 1 is defined as follows. The measuring wire arranged side by side on the power wire is called an electromagnetic wave current sensor. This measuring wire may be composed of any one of a rather long one-dimensional wire, a two-dimensional plane, and a three-dimensional conductor tube. In addition, the measuring wire means a conductor without inductance, not a coil with inductance.

A full electronic overcurrent breaker 300 of the present disclosure includes a sensor unit 310 capable of measuring a magnitude of a current; an amplifier unit 320 that amplifies a signal sensed by the sensor unit; an analog switch unit 325 including a variable resistor that sets a rated current for determining overcurrent; a comparison unit 330 that compares an amplified analog signal with a reference voltage corresponding to a critical overcurrent; an analog-to-digital converter unit 340 that converts the amplified analog signal into digital (e.g. digital signal, digital data); a CPU unit 350 including a function of analyzing digital data, calculating and comparing a tripping time, and generating an output signal capable of controlling a timer and an interrupt, and an external device; a memory (or register) unit 360 that stores a program for determining and controlling the tripping time that continuously decreases as the magnitude of the overcurrent increases and then discontinuously decreases at a critical overcurrent (an instantaneous current); a communication unit 370 that transmits obtained data to the outside; a switch unit 380 that trips overcurrent in response to a signal from an output port of the CPU unit or from an output of the comparison unit to protect an AC power device 382; and a power supply unit 395 that drives a system of the full electronic overcurrent breaker (FIG. 3, FIG. 4, FIG. 5).

The sensor unit 310 is a means capable of sensing a power wire 313 and a current flowing through the power wire 313, and includes a hyun-tak line metal wire 316 (Patent Document 1) parallel to the power wire 313 that senses the electromagnetic wave of the power wire. In this case, a specified separation distance (0≤d≤‘cover thickness of the power wire’) is placed between the power wire and the metal wire.

The amplifier unit 320 has a function of amplifying the analog signal sensed by the sensor unit, and filters may be attached to the amplifier unit 320 to remove noise that may come along the signal prior to amplification of the signal. The signal is amplified using an operational amplifier.

The analog switch unit 325 includes a switch and a resistor for input of a variable resistor that determines the magnitude of the rated current from the outside to determine the overcurrent. The rated current is subdivided by dividing the analog value into 256 equal parts of 8 bits in the analog-to-digital converter.

The comparison unit 330 that compares the instantaneous critical voltage receives and compares the signal voltage amplified by the amplifier unit with a critical voltage corresponding to a critical current corresponding to the instantaneous phenomenon. When the amplified signal voltage is greater than the critical voltage, the output voltage of the comparison unit goes from Low to High or from High to Low.

The analog-to-digital converter (ADC) unit 340 includes a converter that converts the analog signal voltage amplified by the amplifier unit 320 into digital and an analog-to-digital converter that converts an analog rated current from the analog switch unit 325 to digital.

The CPU unit 350 analyzes digital data like a computer, calculates a tripping time, operates according to a program, and includes a timer and an interrupt function.

The memory unit 360 functions to store a program for determining a tripping time that continuously decreases as the overcurrent increases and an interrupt program for determining a tripping time that discontinuously decreases at a critical overcurrent. The memory unit 360 is characterized in that it is organically operated when the CPU unit 350 is driven.

The switch unit 380 for tripping the overcurrent is characterized in that it operates according to the overcurrent tripping signal 384 for a power trip switch from the CPU unit 350 in order to protect the AC power device 382.

The power trip switch includes a relay 388 or a power semiconductor device 389 (FIG. 7). The relay and the power semiconductor device are controlled by a control device 386 of overcurrent trip switches 388 and 389.

The control device 386 of the overcurrent trip switches 388 and 389 includes a field effect transistor, a bipolar transistor, a thyristor (Silicon Controlled Rectifier: SCR), a triac, a phototransistor, a photo SCR, or a photo triac. The overcurrent trip switch includes the relay 388 or the power semiconductor device 389.

The relay is an electromagnet, which means that the switch is operated by electrical power, and includes a solenoid that operates on the same principle as the relay.

The power semiconductor device 389 includes a field effect transistor for power or an inter gate bipolar transistor (IGBT).

The communication unit 370 has a function of communicating with an external device.

The power supply unit 395 supplies power to the full electronic overcurrent breaker 300 of the present disclosure. The power supply unit includes a battery prepared in case power is not supplied to the full electronic overcurrent breaker when the overcurrent is tripped.

The analog-to-digital converter unit, the CPU unit, the memory unit, and the communication unit may be replaced with a microcontroller (MCU) 390 having an integrated function of each unit (FIGS. 4 and 5).

The function that the tripping time continuously decreases as the overcurrent increases includes the overcurrent tripping time T=aR^{-b}+c, R=I_{measured current}/I_{rated current}>1, −7200≤a≤7200, a≠0, −1≤b≤5, b≠0, 0≤c≤(max R)^{-b}. Here, the unit of the overcurrent tripping time is seconds (sec). The value of 7200 is a value obtained by converting 2 hours into seconds. The (max R) is the maximum value of an instantaneous tripping current ratio. For example, when the instantaneous tripping current is defined as 15 times the rated current, the (max R) is 15. When R=1 and c=0, then T=7200 seconds, which is 2 hours. Therefore, the maximum tripping time is limited to within 2 hours according to the international standard IEC 60947-1.

As an example, when R>1, 0<a≤7200, 0<b≤5, and c=0 in the above overcurrent tripping time T, the tripping time by the function of T=aR^{-b} decreases according to the increasing overcurrent as illustrated in FIG. 13. The data of FIG. 13 are illustrated in FIG. 14.

As another example, when R>1, −7200≤a<0, −1≤b<0, 0<c≤(max R)^{-b} in the above overcurrent tripping time T, according to the increasing overcurrent as illustrated in FIG. 15, the tripping time decreases by the function of T=aR^{-b}+c.

As an example of another function, T=a/(Rb−1), which illustrates the divergence near the rated current may be considered. As in FIG. 16, in this function, T decreases as R increases. In this case, the ranges of 0<a≤7200 and 0<b≤15 are suitable (FIG. 16).

In addition, if necessary, a region of overcurrent may be subdivided more than IEC 60947.

In case of instantaneous or short-circuit tripping, the critical current for tripping is defined as (max R), and an output signal of a comparator for instantaneous or short-circuit tripping is input to the interrupt terminal of the CPU unit. Accordingly, the interrupt program of the CPU unit is operated, and the overcurrent is tripped by generating a control signal at an input/output terminal (or port) of the CPU unit.

As another instantaneous or short-circuit tripping method, there is a method in which overcurrent is directly tripped by operating the overcurrent trip switch using the control signal generated from the comparator without interruption of the CPU unit, when the output signal of the comparator obtained by comparing the defined critical current (max R) for tripping with the measured current signal is determined as an instantaneous tripping signal (FIG. 5, FIG. 6B).

A method of tripping overcurrent in the full electronic overcurrent breaker 300 will be described.

Here, a current obtained when the current measured by the current sensor of the metal wire which is the hyun-tak line 316 parallel to the power wire is greater than the rated current input from the analog switch unit 325 is defined as the overcurrent.

As the overcurrent continuously increases from the long time to the short time and the instantaneous time, the analog signal output from the comparison unit is converted to digital in the analog-to-digital converter unit 340, and as the CPU unit determines that it is overcurrent, the control device 386 of the overcurrent trip switches 388 and 389 is controlled by the output signal of the CPU unit to operate the overcurrent trip switches 388 and 389, thereby tripping the overcurrent.

Regarding the operation of the trip switch when it is determined as a critical overcurrent in an instantaneous or short circuit in the full electronic overcurrent breaker 300; the output terminal of the comparison unit is connected to the interrupt terminal of the CPU unit (FIGS. 3 and 4); an output terminal of the CPU unit is connected to the control device 386 of the overcurrent trip switches 388 and 389; the output signal of the comparison unit causes the interrupt function of the CPU unit to operate, and the interrupt subroutine program runs; and the control device 386 of the overcurrent trip switches 388 and 389 is controlled by the output signal of the CPU unit, and the overcurrent trip switches 388 and 389 are operated to trip the overcurrent.

As another means, when it is determined as the critical overcurrent, the output terminal of the comparison unit is not connected to the interrupt terminal of the CPU unit, but is directly connected to the control device 386 of the overcurrent trip switches 388 and 389; and the control device 386 of the overcurrent trip switches 388 and 389 is controlled by the output signal of the comparison unit, and the overcurrent trip switches 388 and 389 are operated to trip the overcurrent.

A latch 335 may be included to latch the output signal of the comparator for signal continuation.

### Advantageous Effects

The full electronic overcurrent breaker using the hyun-tak line current sensor according to the present disclosure has the convenience of automatically sensing the overcurrent and tripping the overcurrent by setting only the rated current regardless of the user's ignorance.

In addition, since the existing CT current sensor, overcurrent setting switch, and overcurrent tripping time setting switch are not used, the circuit breaker can be miniaturized, and the overcurrent tripping satisfying international standards IEC 60947-1 (motor overcurrent circuit breaker) and IEC 60947-2 (circuit, earth leakage, and air circuit breaker), which regulate the tripping time that decreases according to the increasing overcurrent, is possible.

Other objects and advantages of the present disclosure in addition to the above objects and effects will become apparent through the detailed description of the embodiments with reference to the accompanying drawings.

### DESCRIPTION OF DRAWINGS

FIG. 1 illustrates a tripping time for multiples of a rated current for each region (long time, short time, instantaneous time, and short-circuit) as a thermal characteristic of a bimetal.

FIG. 2A illustrates a model divided into several steps of fixation when digitizing an inverse time characteristic of a bimetal.

FIG. 2B illustrates a switch system of setting a tripping time and tripping currents for each step used in the existing electronic circuit breaker.

FIG. 3 illustrates a first internal functional diagram of a full electronic overcurrent breaker of the present disclosure.

FIG. 4 illustrates a second internal functional diagram of a full electronic overcurrent breaker of the present disclosure.

FIG. 5 illustrates a third internal functional diagram of a full electronic overcurrent breaker of the present disclosure.

FIG. 6A illustrates that an output signal obtained by comparing a signal from an amplifier unit with a critical voltage corresponding to a critical overcurrent through a comparison unit is connected to an interrupt terminal of the CPU unit.

FIG. 6B illustrates that an output signal obtained by comparing a signal from an amplifier unit with a critical voltage corresponding to a critical overcurrent through a comparison unit is directly connected to a switch unit through a latch 335.

FIG. 7A illustrates a functional diagram of a switch unit that trips overcurrent using a relay.

FIG. 7B illustrates a functional diagram of a switch unit that trips overcurrent using a power semiconductor device.

FIG. 8 illustrates an AC 250V 16 A single-phase overcurrent power breaker developed as an embodiment of the present disclosure.

FIG. 9 illustrates a layout of the overcurrent tripping experiment environment with the overcurrent breaker of the present disclosure.

FIG. 10 illustrates a flowchart of a main program for tripping overcurrent of a full electronic overcurrent breaker of the present disclosure.

FIG. 11A illustrates a flowchart of a subroutine program of a long time condition connected to the main program of FIG. 10.

FIG. 11B illustrates a flowchart of a subroutine program of a short time condition connected to the main program of FIG. 10.

FIG. 11C illustrates a flowchart of a subroutine program of an instantaneous time condition connected to the main program of FIG. 10.

FIG. 12 illustrates a flowchart of an interruption program operated at a short circuit state.

FIG. 13A illustrates dependence of ‘b’ in an overcurrent tripping time T=7200R^{-b} according to an increasing overcurrent, as a first embodiment of the present disclosure. Here, R=I_{measurement current}/I_{rated current}>1, and 0<b≤3 are satisfied. The coefficient 7200 is a value obtained by converting 2 hours into seconds.

FIG. 13B illustrates dependence of ‘b’ in an overcurrent tripping time T=120R^{-b} according to an increasing overcurrent, as a first embodiment of the present disclosure. Here, R=I_{measurement current}/I_{rated current}>1, and 0<b≤3 are satisfied. The coefficient 120 is a value obtained by converting 2 minutes into seconds.

FIG. 13C illustrates dependence of ‘b’ in an overcurrent tripping time T=20R^{-b} according to an increasing overcurrent, as a first embodiment of the present disclosure. Here, R=I_{measurement current}/I_{rated current}>1, and 0<b≤3 are satisfied. The coefficient 20 is a value arbitrarily set to meet international standards.

FIG. 14 illustrates graphs summarizing FIGS. 13A, 13B, and 13C.

FIG. 15A illustrates dependence of ‘b’ in an overcurrent tripping time T=−7200[R^{-b}−15^{-b}] according to an increasing overcurrent, as a second embodiment of the present disclosure. Here, R=I_{measurement current}/I_{rated current}>1, −≤b<0, and 15^{-b}=intercept c=(max R^{-b}) are satisfied. The value 15 is a case where the maximum R (max R=15) is set, and this value may vary with depending on the setting. The coefficient 7200 is a value obtained by converting 2 hours into seconds.

FIG. 15B illustrates dependence of ‘b’ in an overcurrent tripping time T=−120[R^{-b}−15^{-b}] according to an increasing overcurrent, as a second embodiment of the present disclosure. Here, R=I_{measurement current}/I_{rated current}>1, −1≤b<0, and 15^{-b}=intercept c=(max R^{-b}) are satisfied. The value 15 is a case where the maximum R (max R=15) is set, and this value may vary with depending on the setting. The coefficient 120 is a value obtained by converting 2 minutes into seconds.

FIG. 15C illustrates dependence of ‘b’ in an overcurrent tripping time T=−20[R^{-b}−15^{-b}] according to an increasing overcurrent, as a second embodiment of the present disclosure. Here, R=I_{measurement current}/I_{rated current}>1, −1≤b<0, and 15^{-b}=intercept c=(max R^{-b}) are satisfied. The value 15 is a case where the maximum R (max R=15) is set, and this value may vary with depending on the setting. The coefficient 20 is a value arbitrarily set to meet international standards.

FIG. 16 illustrates the dependence of ‘a’ and ‘b’ in an overcurrent tripping time T=a/(R^{b}−1) according to an increasing overcurrent, as a third embodiment of the present disclosure. Here, R=I_{measurement current}/I_{rated current}>1, a=7200, a=120, a=20, 1≤b≤15 are satisfied. The values of the coefficient ‘a’ are arbitrarily set to meet international standards.

FIGS. 17A and 17B are embodiments of the disclosure according to FIG. 4 of the present disclosure. FIG. 17A illustrates an analog switch and a power wire, which receive the rated current. Here, the hyun-tak line, which is the current sensor, is hidden underneath the power conductor. FIG. 17B illustrates the electronic part of FIG. 4 of the present disclosure.

### BEST MODE

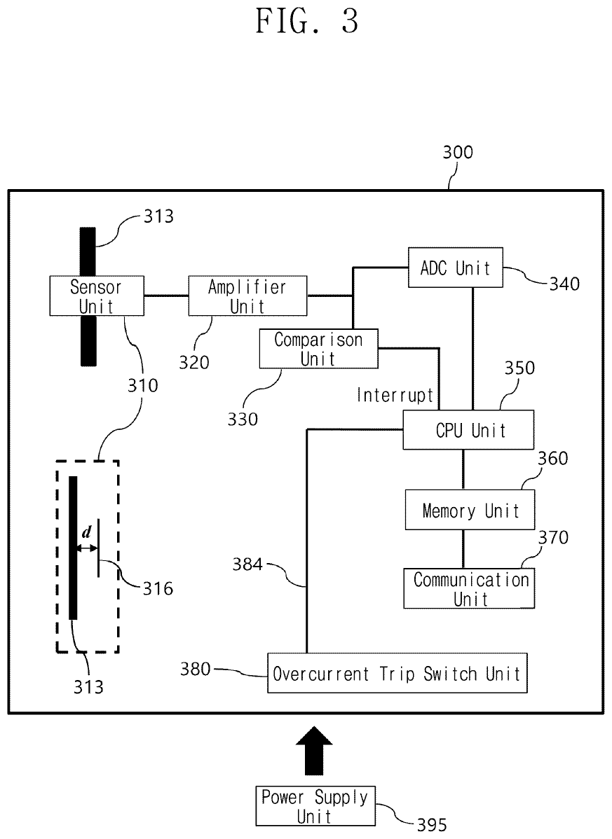

FIG. 3 is a diagram illustrating the best mode for carrying out the present disclosure.

### Mode for Invention

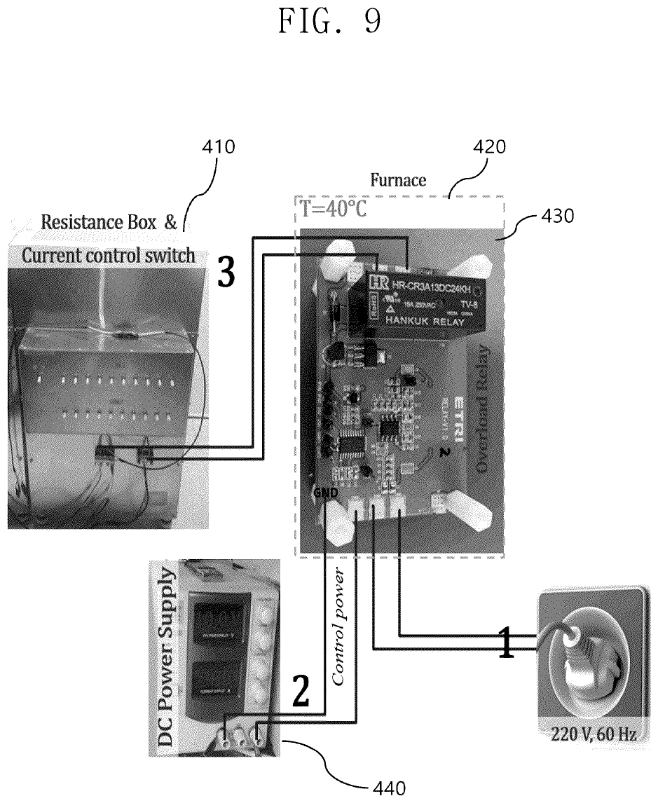

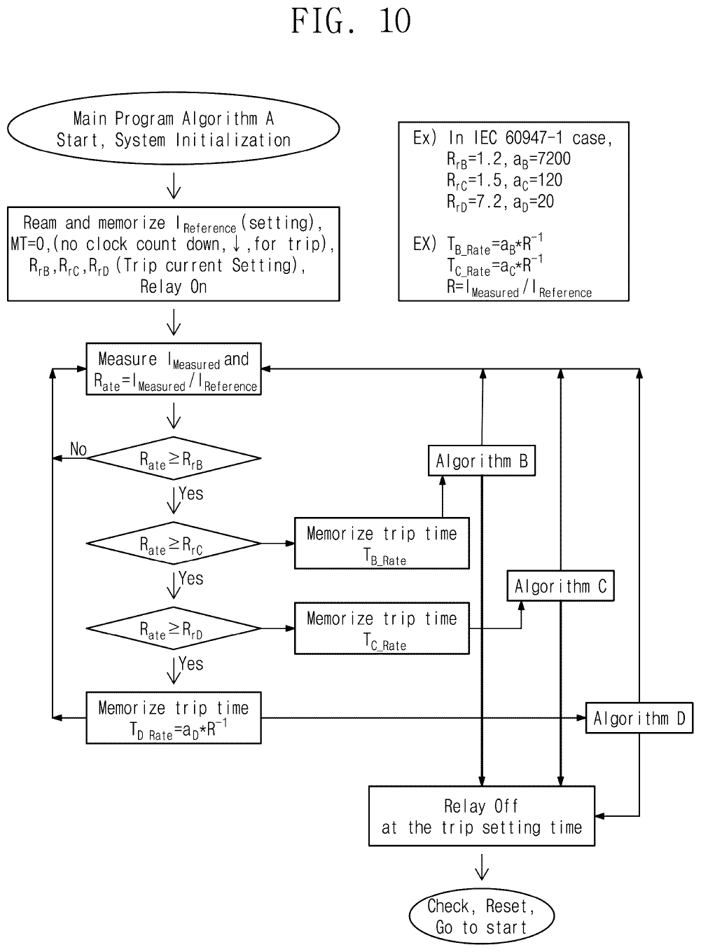

As an embodiment of the present disclosure, an example of an overcurrent tripping operation in an environment prepared according to the experimental layout of FIG. 9 will be described using the full electronic overcurrent breaker 300 manufactured in accordance with the international standard IEC 60947-4-1 and the single-phase AC 250V 16 A relay switch 388 of FIG. 8. The circuit breaker uses a microcontroller (MCU) 390 of a 32-bit by ST-micro company with the analog-to-digital converter unit, the memory unit, the timer unit, digital input/output ports, the interrupt function, and communication function, instead of an independent CPU (Central Processing Unit). To trip the overcurrent with the relay, it is designed to directly output the signal for controlling the 250V 16 A relay 388 from the MCU. The switch 386 for controlling the relay uses a switch in which a field effect transistor and a bipolar transistor are combined. The hyun-tak line 316 parallel to the power wire 313 in Prior Patent document 1 is used as the current sensor, and the output signal of the hyun-tak line 316 is amplified by an operational amplifier 320. The formula for reducing the tripping time according to the increasing overcurrent of the present disclosure is programmed and stored in a memory in the MCU 390, and the overcurrent breaker is operated according to the program created by the flowchart of FIG.10.

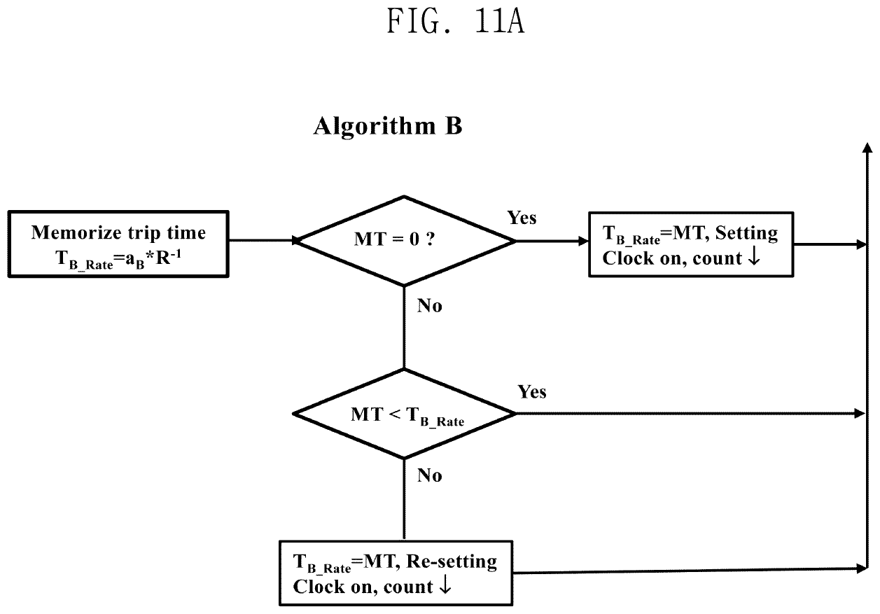

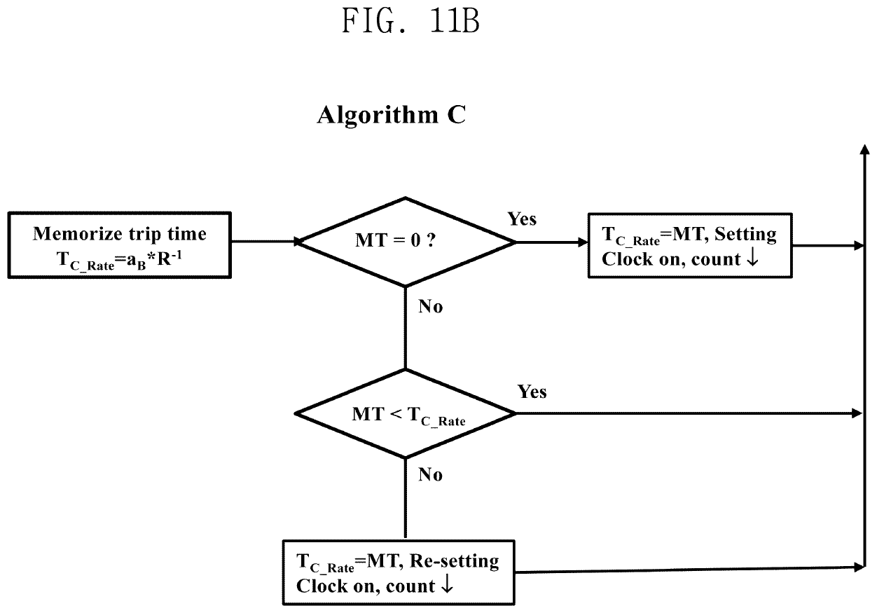

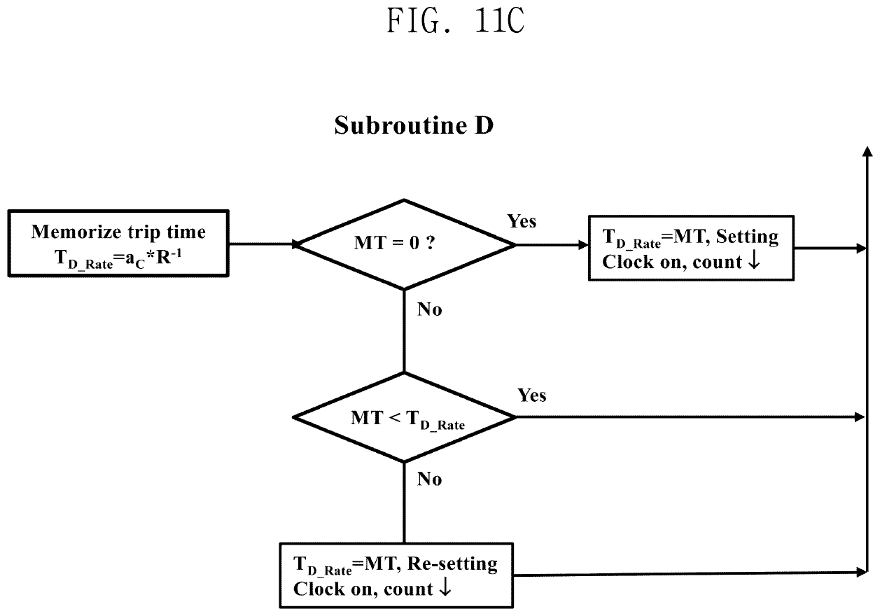

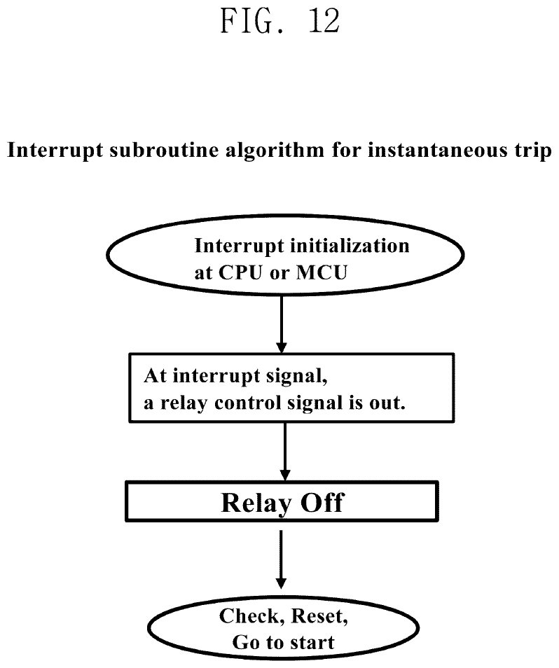

A flowchart of a program (main program; algorithm A) of the full electronic overcurrent breaker of the present disclosure is illustrated in FIG. 10, a flowchart of a tripping algorithm (algorithm B) at 1.2≤R<1.5 is illustrated in FIG. 11A, a flowchart of a tripping algorithm (algorithm C) at 1.5≤R<7.2 is illustrated in FIG. 11B, and a flowchart of a tripping algorithm (algorithm D) at 7.2≤R is illustrated in FIG. 11C. A flowchart of the interrupt subroutine algorithm for instantaneous time is illustrated in FIG. 12.

The above overcurrent tripping experiment is performed in a

laboratory environment constructed according to a layout of FIG. 9. Since there is no large current in the laboratory, the rated current I_{Rated current}≡I_{Reference} is set to 3 A. When the switch of the resistance box 410 is turned on, the current increases by 1 to 3 A, so that it can output up to 60 A. Current flowed from 1 to 45 A (15 times of the rated current). As the overcurrent increases, the tripping time decreases, and there is no breakdown of the relay due to the very short tripping time at a large current.

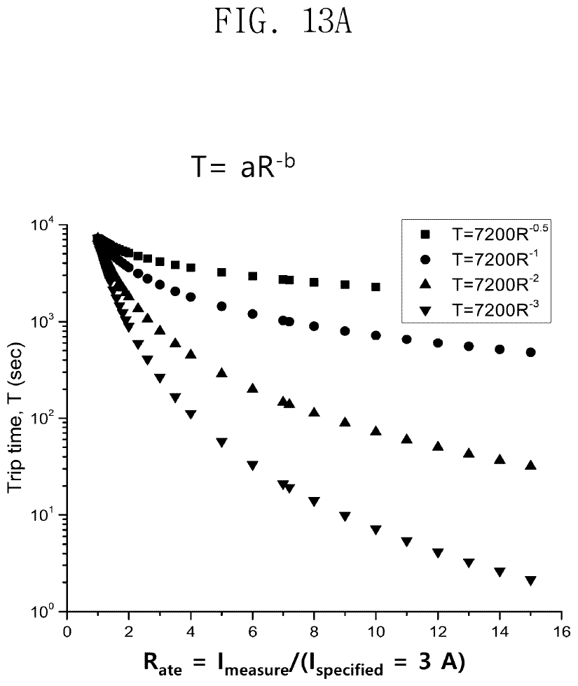

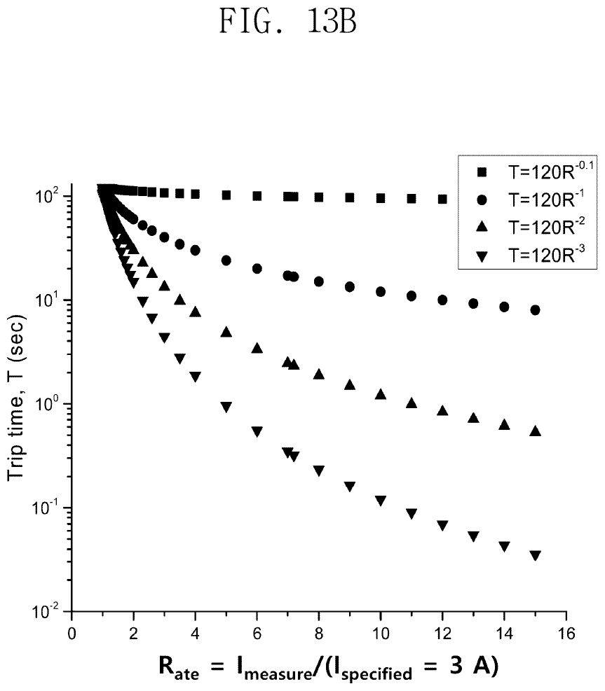

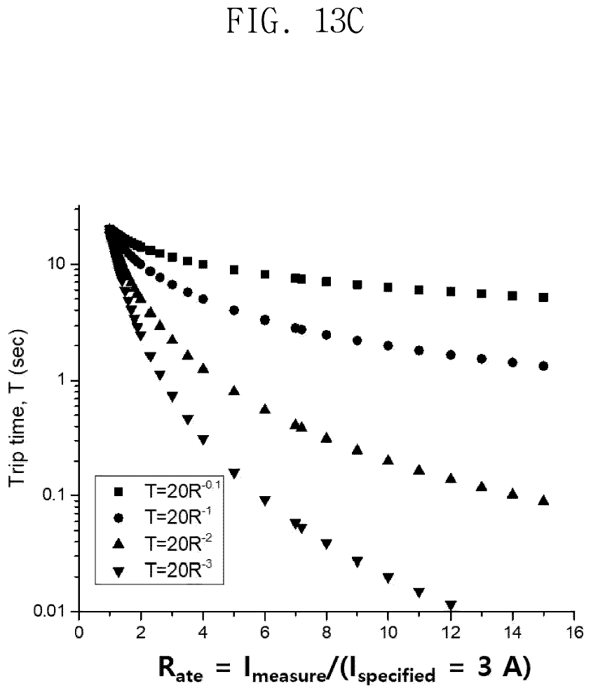

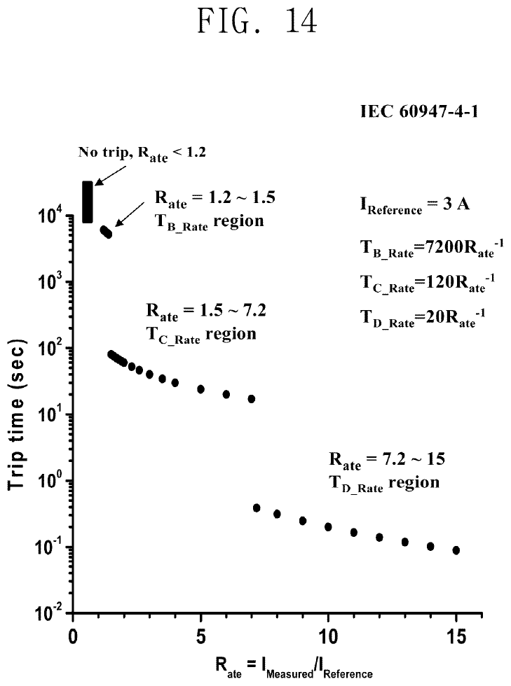

In the overcurrent circuit breaker of FIG. 8 of the present disclosure, the tripping time T=aR^{-b} formula of B, C, and D is programmed and stored in the memory unit 350 inside the microcontroller unit 390, and the overcurrent circuit breaker is operated according to the value. A test is conducted according to the international standard IEC 60947-4-1 in the table above in a state that a load 410 capable of flowing current up to 60 A of overcurrent with respect to a rated current of 3 A is connected to the power wire 313 while increasing the current of the load 410 step by step. As a result, there was no interruption at the rated current, and it is tripped after about 6,000 seconds at R=measured current/rated current=1.2, tripped after about 80 seconds at R=1.5, and tripped after about 2.7 seconds at R=7.2. In the tripping time, data operated according to the program are illustrated in FIGS. 13A, 13B, and 13C. The full data are illustrated in FIG. 14.

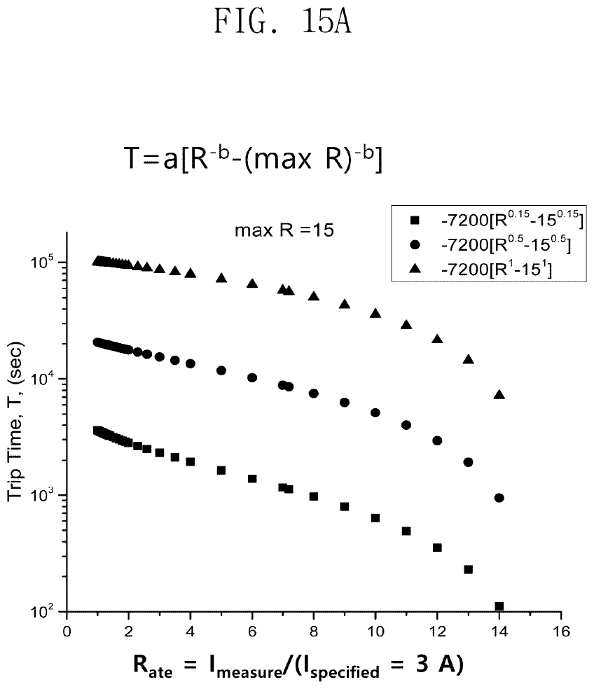

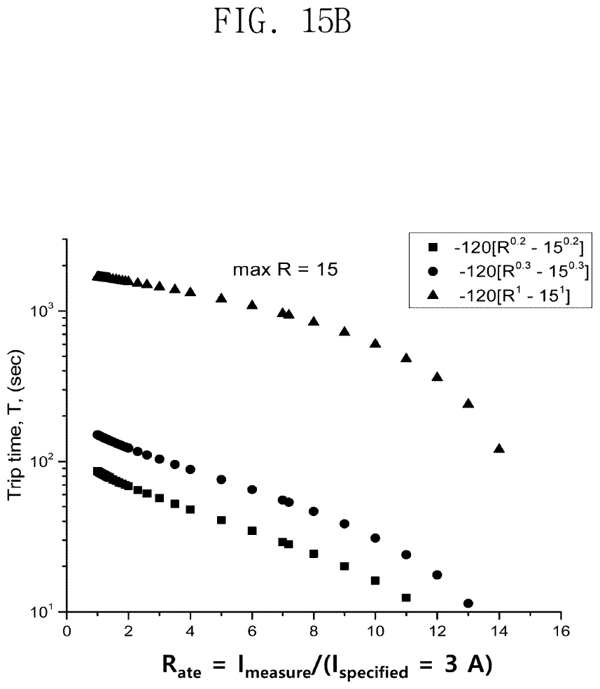

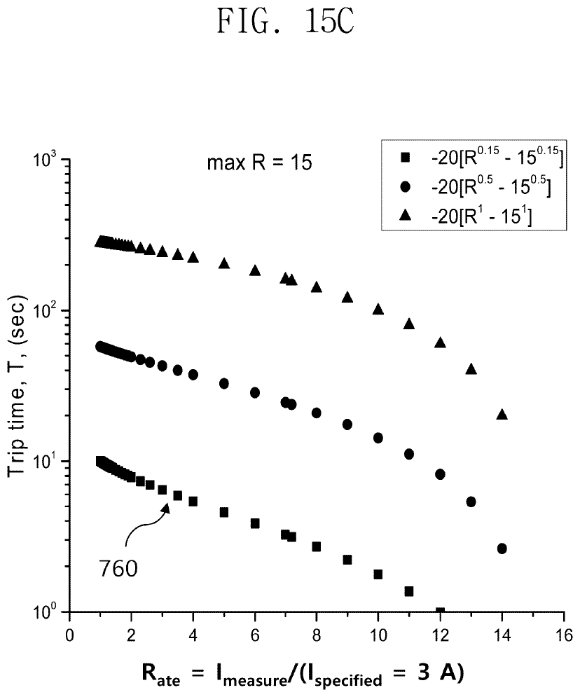

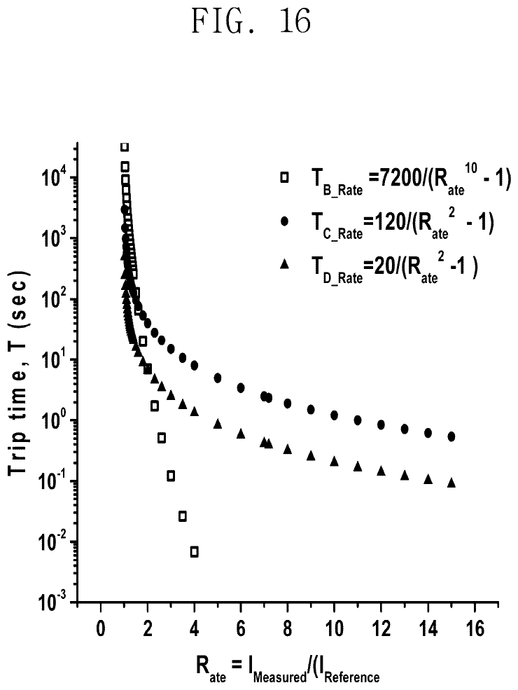

Accordingly, it was confirmed that the tripping time decreases as the overcurrent increases even when the formula for tripping time under other conditions, T=aR^{-b}−(max R=15^{-b}), is changed. Data related to this are illustrated in FIGS. 15A, 15B, and 15C. In addition, it was confirmed that the tripping time decreases as the overcurrent increases even when the formula for tripping time under other conditions, T=a/(R^{b}−1), is changed. Data for this experiment are illustrated in FIG. 16.

However, the scope of the present disclosure is not limited thereto, and the full electronic overcurrent breaker according to embodiments of the present disclosure may be implemented as follows.

In one embodiment, the full electronic overcurrent breaker may include the hyun-tak line AC current sensor that measures the magnitude of the overcurrent in the AC power system. The full electronic overcurrent breaker may continuously decrease the tripping time when the magnitude of the measured overcurrent is less than the magnitude of the critical overcurrent, and may discontinuously decrease the tripping time when the magnitude of the measured overcurrent is greater than or equal to the magnitude of the critical overcurrent. The overcurrent may be tripped at the tripping time.

In an embodiment, to protect a sensor unit including the hyun-tak line AC current sensor, an amplifier unit generating an amplified analog signal by amplifying a signal output from the sensor unit, a comparison unit comparing the amplified analog signal with a reference voltage corresponding to the critical overcurrent, an analog-to-digital converter unit converting the amplified analog signal into digital data, a CPU unit that calculates the tripping time based on the digital data, performs an interrupt function, and outputs an overcurrent tripping signal for controlling external devices, a memory unit that stores a program for determining and controlling the tripping time based on the magnitude of the measured overcurrent, and an AC power device, a switch unit controlling a device for controlling an overcurrent trip switch based on the overcurrent tripping signal such that the overcurrent trip switch for tripping the overcurrent operates, and a power supply unit providing the driving power to the hyun-tak line AC current sensor, the amplifier unit, the comparison unit, the analog-to-digital converter unit, the CPU unit, the memory unit, and the switch, may be provided.

In an embodiment, the amplifier unit may include an operational amplifier.

In an embodiment, the comparison unit may include a comparator that compares the voltage of the amplified analog signal with the reference voltage corresponding to the critical overcurrent.

In an embodiment, the analog-to-digital converter unit may include an analog-to-digital converter for converting the amplified analog signal into digital data.

In an embodiment, the analog-to-digital converter unit, the CPU unit, and the memory unit may be implemented with a microcontroller (MCU).

In one embodiment, the program determines the continuously decreasing tripping time based on Equation 1, wherein the Equation 1 may define T=aR^{-b}, T is the tripping time, R=I_{measured current}/I_{rated current}>1, 0<a≤7200, and 0<b≤5.

In an embodiment, the program determines the continuously decreasing tripping time based on Equation 2, wherein the Equation 2 may define T=aR^{-b}+c, T is the tripping time, R=I_{measured current}/I_{rated current}>1, −7200≤a<0, −1≤b<0, b≠0, and 0≤c≤(max R)^{-b}.

In an embodiment, the program determines the continuously

decreasing tripping time based on Equation 3, wherein the Equation 3 may define T=a/(R^{b}−1), T may be the tripping time, R=I_{measured current}/I_{rated current}>1, 0<a≤7200, and 0<b≤15.

In an embodiment, when an output signal obtained by comparing a voltage of the amplified analog signal with the reference voltage corresponding to the critical overcurrent using a comparator of the comparison unit corresponds to the overcurrent, an output terminal of the comparator is connected to an interrupt terminal of the CPU unit, and an output terminal of the CPU unit is connected to the device for controlling the overcurrent trip switch. In addition, a subroutine program operates to perform the interrupt function by the CPU unit based on the output signal of the comparator, and the overcurrent trip switch may be operated by controlling a device for controlling the overcurrent trip switch based on the output signal of the CPU unit.

In an embodiment, the switch unit may include the device for controlling the overcurrent trip switch and a relay or a solenoid which is a switch that directly trips the overcurrent.

In an embodiment, the switch unit may include the device for controlling the overcurrent trip switch and a power semiconductor device which is a switch that directly trips the overcurrent.

In an embodiment, the device for controlling the overcurrent trip switch controlled by the switch unit may include at least one of a field effect transistor, a bipolar transistor, a thyristor (Silicon Controlled Rectifier (SCR)), a triac, a photo transistor, a photo SCR, and a photo triac.

In one embodiment, the power supply unit, when the power supplied to the power supply unit is tripped, may include a battery that provides the driving power to the hyun-tak line AC current sensor, the amplifier unit, the comparison unit, the analog-to-digital converter unit, the CPU unit, the memory unit, and the switch unit.

In an embodiment, to protect a sensor unit including the hyun-tak line AC current sensor, an amplifier unit generating an amplified analog signal by amplifying a signal output from the sensor unit, a comparison unit comparing the amplified analog signal with a reference voltage corresponding to the critical overcurrent, an analog-to-digital converter unit, a CPU unit, a microcontroller (MCU) unit including a memory unit, and an AC power device, a switch unit controlling a device for controlling an overcurrent trip switch based on the output signal of the comparison unit such that the overcurrent trip switch for tripping the overcurrent operates, and a power supply unit providing the driving power to the hyun-tak line AC current sensor, the amplifier unit, the comparison unit, the MCU unit, and the switch unit, may be provided.

In an embodiment, when an output signal obtained by comparing a voltage of the amplified analog signal with the reference voltage corresponding to the critical overcurrent using a comparator of the comparison unit corresponds to the overcurrent, the output terminal of the comparator is directly connected to the device for controlling the overcurrent trip switch without being connected to the interrupt terminal of the CPU unit, and thus a relay or a solenoid for controlling the overcurrent trip switch may be operated by the output signal of the comparator.

In an embodiment, the device for controlling the overcurrent trip switch controlled by the switch unit may include at least one of a field effect transistor, a bipolar transistor, a thyristor, a triac, a photo transistor, a photo SCR, and a photo triac.

In one embodiment, the power supply unit, when the power supplied to the power supply unit is tripped, may include a battery that provides the driving power to the hyun-tak line AC current sensor, the amplifier unit, the comparison unit, the analog-to-digital converter unit, the CPU unit, the memory unit, and the switch unit.

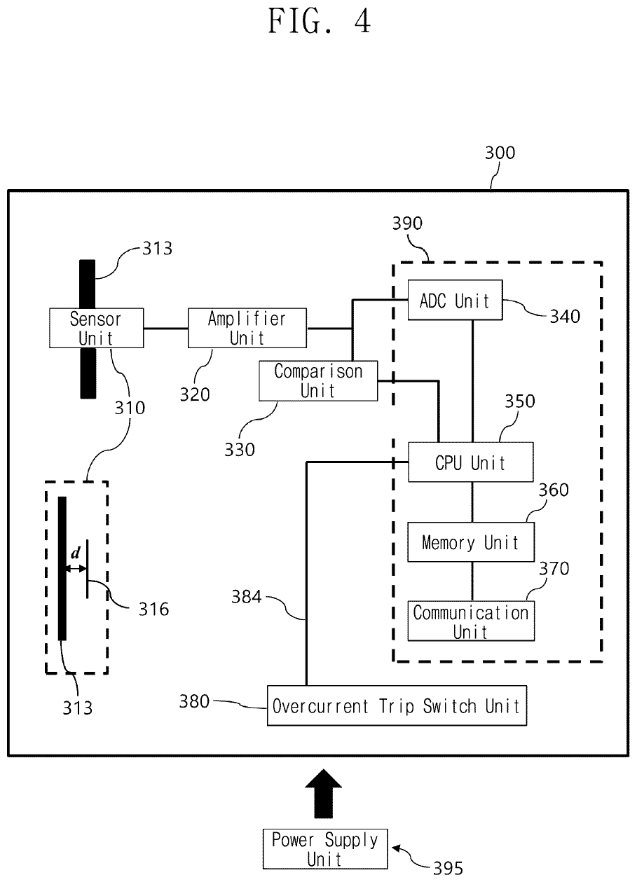

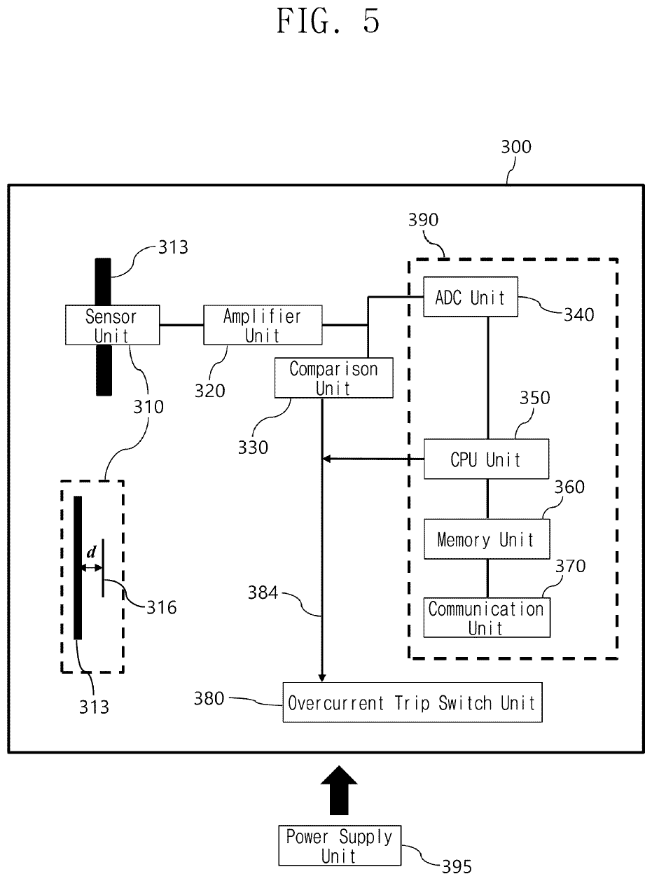

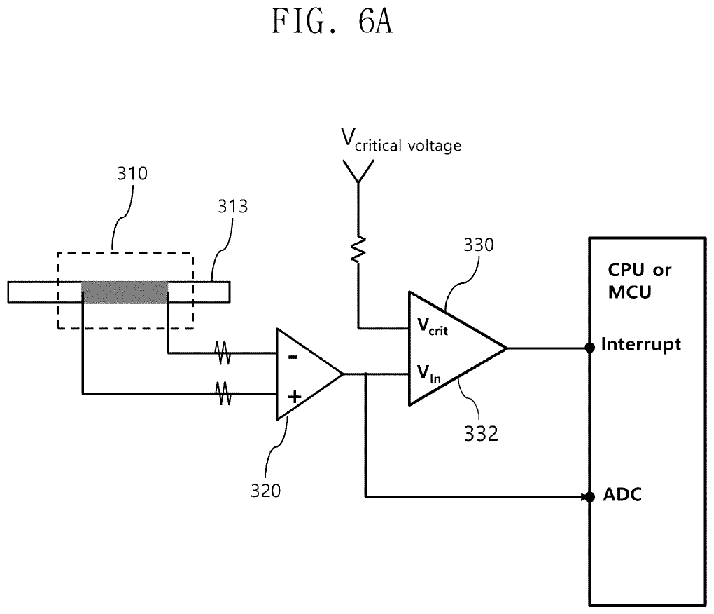

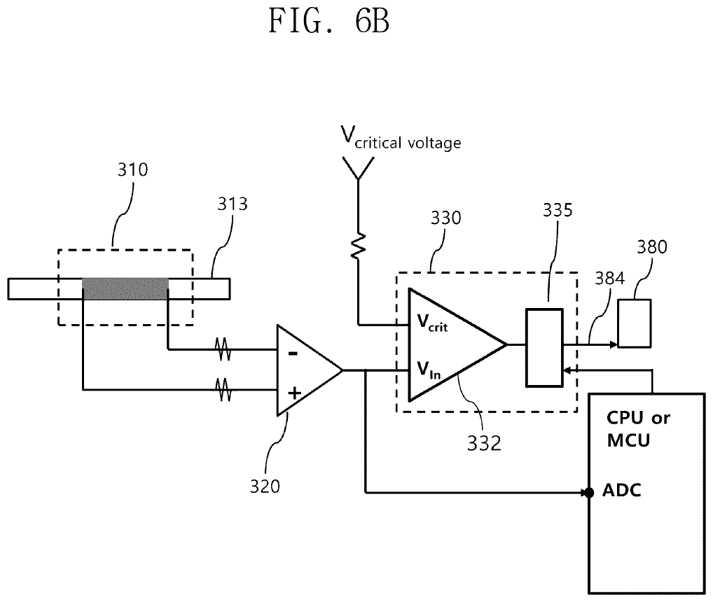

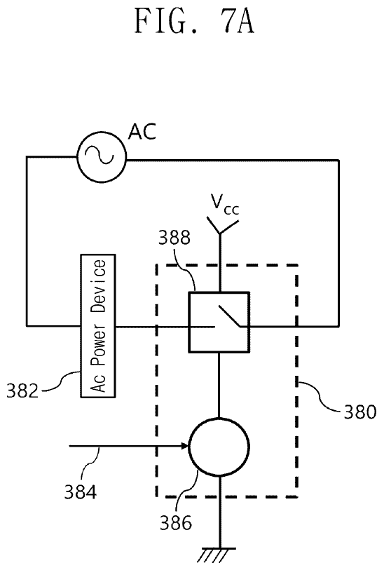

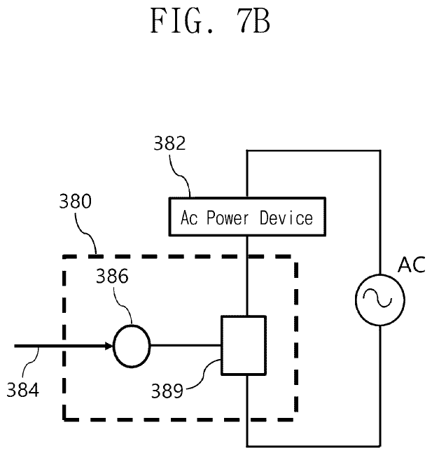

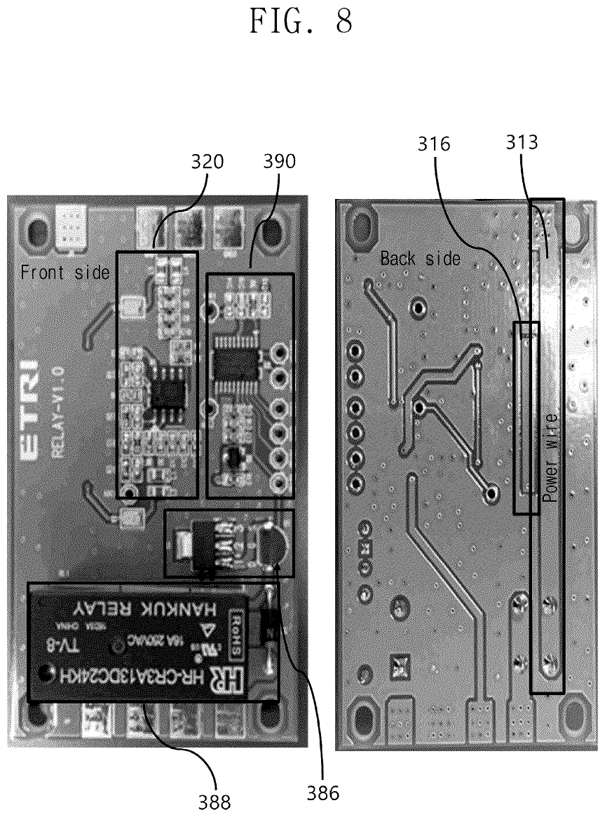

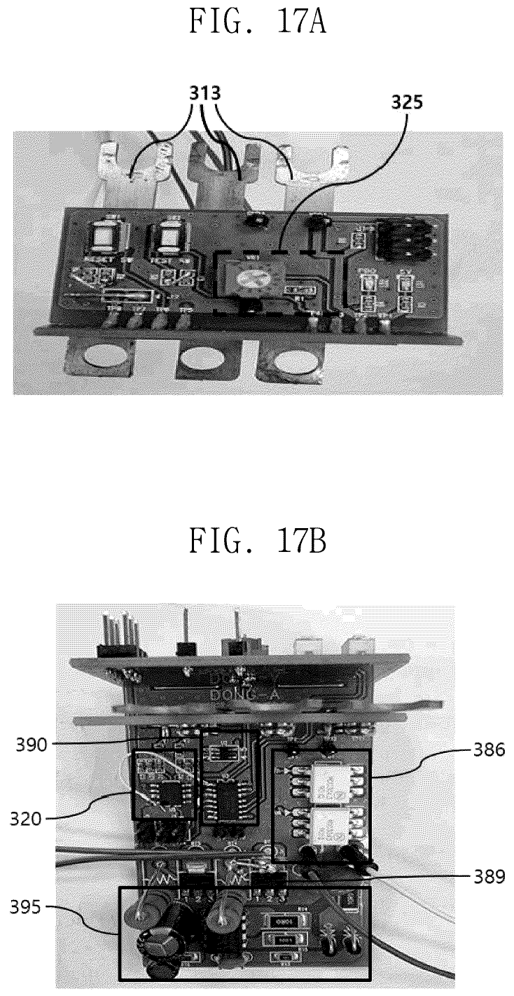

As a further embodiment, FIGS. 17A and 17B illustrate the disclosure according to FIG. 4. FIG. 17A illustrates the analog switch unit 325 for setting the rated current at the top without illustrating the hyun-tak line 316 as a current sensor under the power wire 313. FIG. 17B corresponds to the electronic part of the full electronic overcurrent breaker 300 and illustrates the MCU unit 390 including the CPU unit, the memory unit, the analog-to-digital converter unit, and the comparison unit, the amplifier unit 320 that amplifies the signal of the measured current, the electronic trip switches 386 and 389 that trip the power, and the power supply unit 395. The full electronic overcurrent breaker of FIGS. 17A and 17B has a specification of instantaneous current of 144 to 220 A and short-circuit current of 220 A or more for the maximum rated current of 22 A. The full electronic overcurrent breaker of FIGS. 17A and 17B catches instantaneous or short-circuit current within 4 ms (¼ wavelength) using MCU clock 20 MHz, comparator, the internal interrupt program of FIG. 12, and the semiconductor device for tripping the power. For reference, this developed circuit breaker allows current to flow up to 300 A or more, and uses a triac 389, a power semiconductor device, as an electronic trip, not a relay, when tripping.

The above description are specific embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. Therefore, the scope of the present disclosure should not be limited to the above-described embodiments, but should be defined by the claims described below as well as the claims and equivalents of the present disclosure.

### INDUSTRIAL APPLICABILITY

The present disclosure relates to a power circuit breaker. In more detail, It can be used for a full electronic overcurrent circuit breaker that has a tripping time that decreases as the overcurrent increases and has an instantaneous critical characteristic at the critical tripping current.

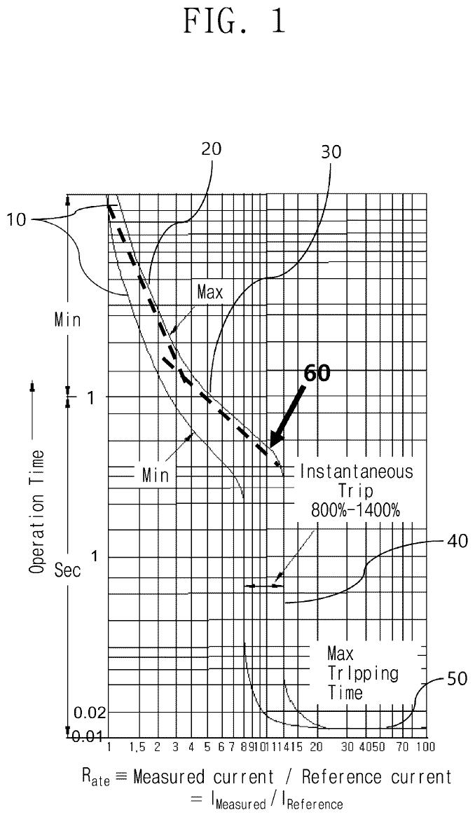

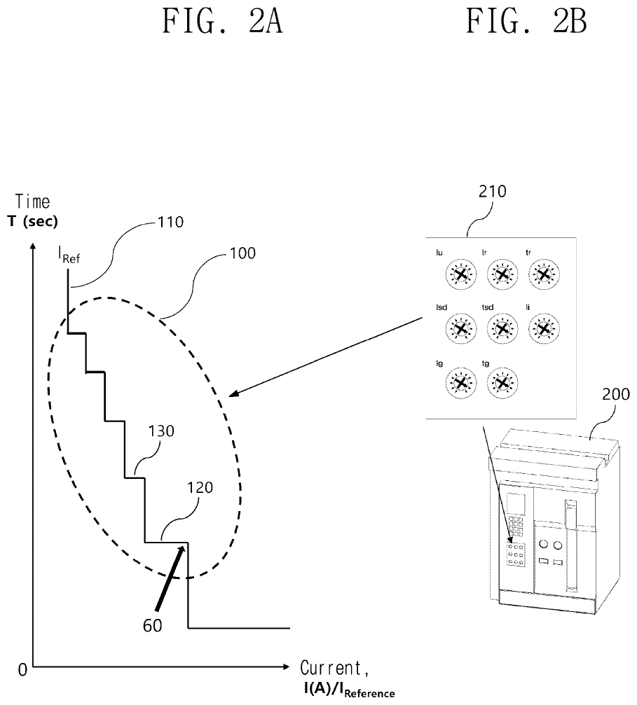

1. A full electronic overcurrent circuit breaker comprising:
continuously decreasing (a long time, a short time, and an instantaneous time) a tripping time up to 7.2 to 14 times or less (FIG. 1) of a rated current as the rated current increases by programmatically comparing a measured current which is measured as an analog signal and converted into digital by a current sensor of a metal wire parallel to a power wire measuring an AC current in an AC power system with the rated current which is input to an analog switch 325 of a variable resistor and is converted into digital; and
when the measured analog current before being converted into the digital measured by the same sensor is an analog value exceeding (FIG. 1) 7.2 to 14 times of a maximum rated current and is greater than a critical overcurrent set in a comparator, tripping power within 30 milliseconds from 7.2 times of the maximum rated current to 14 times of the maximum rated current within 60 milliseconds, and tripping the power within a tripping time of FIG. 1 at more than 14 times (short-circuit) of the maximum rated current.

2. The full electronic overcurrent breaker of claim 1, wherein the full electronic overcurrent breaker includes:
a sensor unit 310 including a hyun-tak line AC current sensor;
an amplifier unit 320 configured to amplify a signal output from the sensor unit 310 to generate an amplified analog signal;
an analog switch unit 325 configured to input the rated current for determining an overcurrent of the full electronic overcurrent breaker;
a comparison unit 330 configured to compare the amplified analog signal with a reference voltage corresponding to the critical overcurrent;
an analog-to-digital converter unit 340 including an analog-to-digital converter configured to convert the amplified analog signal into digital data and an analog-to-digital converter configured to convert an analog rated current into digital in the analog switch unit 325;
a CPU (Central Processing Unit) unit 350 configured to calculate the tripping time based on the digital data, to perform an interrupt function, and to output an overcurrent tripping signal 384 for controlling an external device;
a memory unit 360 configured to store a program for determining and controlling the tripping time based on a measured magnitude of the overcurrent;
a switch unit 380 configured to control a device 386 for controlling overcurrent trip switches such that the overcurrent trip switches 388 and 389 that trips the overcurrent operate, based on the overcurrent tripping signal 384, to protect an AC power device 382; and
a power supply unit 395 configured to provide driving power to the hyun-tak line AC current sensor, the amplifier unit, the comparison unit, the analog-to-digital converter unit, the CPU unit, the memory unit, and the switch unit.

3. The full electronic overcurrent breaker of claim 2, wherein the amplifier unit 320 includes an operational amplifier.

4. The full electronic overcurrent breaker of claim 2, wherein the comparison unit 330 includes a comparator 332 configured to compare a voltage of the amplified analog signal with the reference voltage corresponding to the critical overcurrent.

5. The full electronic overcurrent breaker of claim 2, wherein the analog-to-digital converter unit 340 includes an analog-to-digital converter configured to convert the amplified analog signal into the digital data.

6. The full electronic overcurrent breaker of claim 2, wherein the analog-to-digital converter unit, the CPU unit, and the memory unit are replaced by a one-chip microcontroller (MCU) having a function of the analog-to-digital converter unit, a function of the CPU unit, and a function of the memory unit.

7. The full electronic overcurrent breaker of claim 1, wherein, in the continuously decreasing of the tripping time of overcurrent,
Equation 1 defines T=aR^{-b}, T is the tripping time, R=I_{measured current}/I_{rated current>}1, 0<a≤7200, and 0<b≤5.

8. The full electronic overcurrent breaker of claim 1, wherein, in the continuously decreasing of the tripping time of overcurrent,
Equation 2 defines T=aR^{-b}+c, T is the tripping time, R=I_{measured current}/I_{rated current}>1, −7200≤a<0, −1≤b<0, b≠0, and 0≤c≤(max R)^{-b}.

9. The full electronic overcurrent breaker of claim 1, wherein, in the continuously decreasing of the tripping time of overcurrent,
Equation 3 defines T=a/(R^{b}−1), T is the tripping time, R=I_{measured current}/I_{rated current}>1, 0<a≤7200, and 0<b≤15.

10. The full electronic overcurrent breaker of claim 2, wherein, in a discontinuous decrease of the tripping time in the critical overcurrent,
an output terminal of the comparison unit is connected to an interrupt terminal of the CPU unit in terms of hardware;
an output terminal of the CPU unit is connected to the device for controlling the overcurrent trip switch;
in a comparator 332 of the comparison unit, when it is determined that an output signal obtained by comparing a voltage of the amplified analog signal with the reference voltage corresponding to the critical overcurrent is the overcurrent; and
as an interrupt subroutine program of the CPU unit operates, the device 386 for controlling the overcurrent trip switch is controlled by the output signal of the CPU unit, and the overcurrent trip switches 388 and 389 are operated.

11. The full electronic overcurrent breaker of claim 2, wherein the switch unit 380 includes the device 386 for controlling the overcurrent trip switch and a relay 388 or a solenoid 388 which is a switch that directly trips the overcurrent.

12. The full electronic overcurrent breaker of claim 2, wherein the switch unit 380 includes the device 386 for controlling the overcurrent trip switch and a power semiconductor device 389 which is a switch that directly trips the overcurrent.

13. The full electronic overcurrent breaker of claim 2, wherein the device 386 for controlling the overcurrent trip switch controlled by the switch unit 380 includes at least one of a field effect transistor, a bipolar transistor, a thyristor (Silicon Controlled Rectifier (SCR)), a triac, a photo transistor, a photo SCR, and a photo triac.

14. The full electronic overcurrent breaker of claim 2, wherein, in the comparison unit 330 and the switch unit 380,
through a comparator 332 of the comparison unit, when it is determined that an output signal obtained by comparing a voltage of the amplified analog signal with the reference voltage corresponding to the critical overcurrent is the overcurrent: and
as an output terminal 384 of the comparator is directly connected to the device 386 for controlling the overcurrent trip switch without being connected to an interrupt terminal of the CPU unit, a relay or a solenoid for controlling the overcurrent trip switch is operated by the output signal of the comparator 332.
